(19) United States
(12) Patent Application Publication
(10) Pub. No.: US 2016/0353394 A1
(43) Pub. Date: Dec. 1, 2016

(54) RADIO COMMUNICATION DEVICE

(71) Applicant: FUJITSU LIMITED, Kawasaki-shi (JP)

(72) Inventor: Tsuneaki TADANO, Sendai (JP)

(21) Appl. No.: 15/094,959

(22) Filed: Apr. 8, 2016

(30) Foreign Application Priority Data
Jun. 1, 2015 (JP) 2015-111758

(51) Int. Cl. H04W 52/52; H04L 5/14; H03F 1/02; H04W 24/08

(52) U.S. Cl. CPC H04W 52/52; H04W 24/08; H04L 5/14; H03F 1/0288; H03F 2200/555

(57) ABSTRACT

A radio communication device includes an amplifier configured to amplify an electric signal to be transmitted; and a controlling section configured to set an operating point voltage of the amplifier to a first voltage for increasing a temperature in the amplifier in a non-transmission period after a reception period and before a transmission period and set the operating point voltage of the amplifier to a second voltage that is lower than the first voltage and higher than a pinch-off voltage in the transmission period.

### CROSS-REFERENCE TO RELATED APPLICATION

This application is based upon and claims the benefit of priority of the prior Japanese Patent Application No. 2015-111758, filed on Jun. 1, 2015, the entire contents of which are incorporated herein by reference.

### FIELD

The embodiments discussed herein are related to a radio communication device.

### BACKGROUND

In radio communication systems, a time division duplex (TDD) scheme in which “reception periods” and “transmission periods” are chronologically separated tends to be used in order to improve the efficiency of using frequencies.

In a radio communication device to which the TDD scheme is applied, control is executed to reduce an operation time of an amplifier as much as possible in order to maintain receiving sensitivity, reduce power to be consumed, and the like. As a method of reducing the operation time of the amplifier, there is a method of setting an operating point voltage of the amplifier to a pinch-off voltage for stopping an amplification operation in “reception periods” and setting the operating point voltage of the amplifier to a voltage higher than the pinch-off voltage in “transmission periods”.

An example of related art is 3GPP TS 36, 104 V10.2.0 (2011-04).

However, in the method of setting the operating point voltage of the amplifier to a voltage higher than the pinch-off voltage in the “transmission periods”, the amplifier is rapidly activated and thus the temperature of the amplifier that temporarily decreases due to the stop of the amplification operation rapidly increases. The rapid increase in the temperature of the amplifier deteriorates AM/AM and AM/PM characteristics of the amplifier and accordingly causes an increase in an adjacent channel leakage ratio (ACLR).

It is, therefore, desirable to provide a method of suppressing the increase in the ACLR that is caused by a change in the temperature of the amplifier upon the activation of the amplifier.

A technique disclosed herein was devised under the aforementioned circumstances, and an object of the technique disclosed herein is to provide a radio communication device that may suppress an increase in an ACLR that is caused by a change in the temperature of an amplifier upon the activation of the amplifier.

### SUMMARY

According to an aspect of the embodiments, a radio communication device includes an amplifier configured to amplify an electric signal to be transmitted; and a controlling section configured to set an operating point voltage of the amplifier to a first voltage for increasing a temperature in the amplifier in a non-transmission period after a reception period and before a transmission period and set the operating point voltage of the amplifier to a second voltage that is lower than the first voltage and higher than a pinch-off voltage in the transmission period.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a block diagram illustrating an example of a configuration of a radio communication device according to a first embodiment;

FIG. 2 is a diagram describing an example of relationships between a temperature increase voltage, a bias voltage, and a pinch-off voltage;

FIG. 3 is a diagram describing process operations of the radio communication device according to the first embodiment;

FIG. 4 is a diagram describing process operations of a radio communication device according to a comparative example;

FIG. 5 is a flowchart indicating an example of the flow of the process operations of the radio communication device according to the first embodiment;

FIG. 6 is a block diagram illustrating an example of a configuration of a radio communication device according to a second embodiment;

FIG. 7 is a diagram illustrating an example of association data in which a traffic amount and a temperature increase voltage are associated with each other;

FIG. 8 is a diagram describing process operations of the radio communication device according to the second embodiment;

FIG. 9 is a flowchart indicating an example of the flow of the process operations of the radio communication device according to the second embodiment; and

FIG. 10 is a diagram illustrating an example of a hardware configuration of each of the radio communication devices.

### DESCRIPTION OF EMBODIMENTS

Hereinafter, embodiments of a radio communication device disclosed herein are described in detail with reference to the accompanying drawings. The technique disclosed herein is not limited to the embodiments. In the embodiments, configurations that have the same function are indicated by the same reference numeral, and duplicated descriptions are omitted.

### First Embodiment

### Example of Configuration of Radio Communication Device

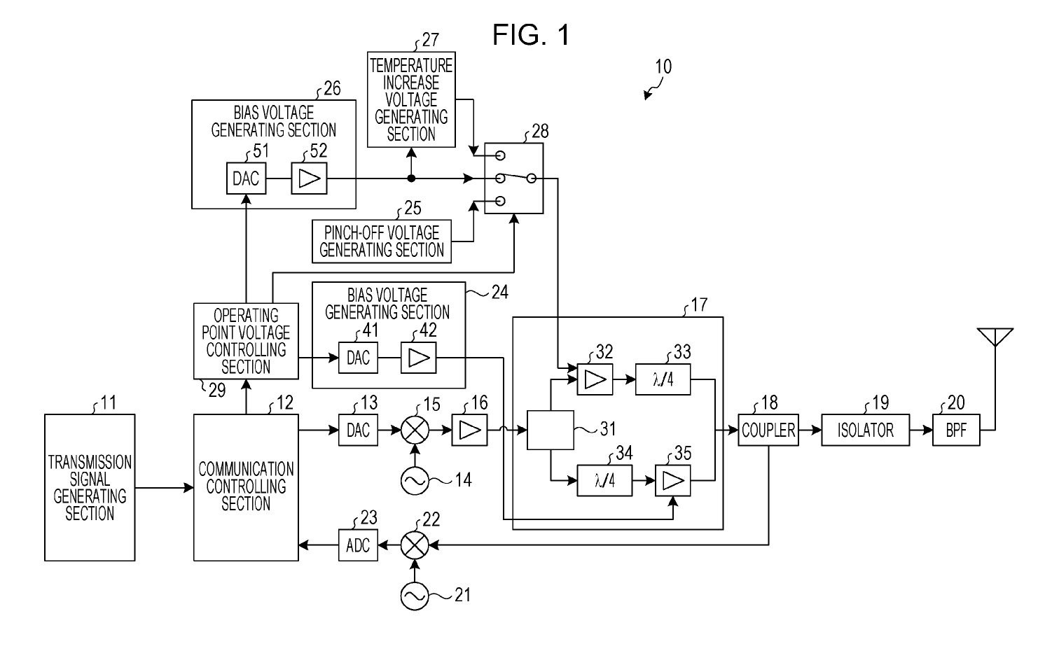

FIG. 1 is a block diagram illustrating an example of a configuration of a radio communication device according to the first embodiment. Referring to FIG. 1, a radio communication device 10 includes a transmission signal generating section 11, a communication controlling section 12, a digital-to-analog converter (DAC) 13, an oscillator 14, a mixer 15, an amplifier 16, a Doherty amplifying circuit 17, and a coupler 18. In addition, the radio communication device 10 includes an isolator 19, a bandpass filter (BPF) 20, an oscillator 21, a mixer 22, and an analog-to-digital converter (ADC) 23. In addition, the radio communication device 10 includes a bias voltage generating section 24, a pinch-off voltage generating section 25, a bias voltage generating section 26, a temperature increase voltage generating section 27, a voltage switch 28, and an operating point voltage controlling section 29. A time division duplex (TDD) scheme is applied to the radio communication device 10.

The transmission signal generating section 11 generates a transmission signal that is a digital signal, and the transmission signal generating section 11 outputs the generated transmission signal to the communication controlling section 12.

The communication controlling section 12 calculates a distortion compensation coefficient for minimizing the difference between the transmission signal received from the transmission signal generating section 11 and a feedback signal received from the ADC 23 and updates a stored distortion compensation coefficient to the calculated distortion compensation coefficient. Then, the communication controlling section 12 uses the updated distortion compensation coefficient to compensate for distortion of the transmission signal. After that, the communication controlling section 12 outputs, to the DAC 13, the transmission signal subjected to the distortion compensation.

The communication controlling section 12 controls timings of a “reception period”, “transmission period”, and “gap period” between the reception period and the transmission period in the time division duplex scheme. Then, the communication controlling section 12 outputs, to the operating point voltage controlling section 29, information indicating start timings and end timings of the “reception period”, “transmission period”, and “gap period”. If the radio communication device 10 is a base station, the “reception period” in which uplink transmission from a terminal to the base station is executed is also referred to as an “uplink period” and the “transmission period” in which downlink transmission from the base station to the terminal is executed is also referred to as a “downlink period”. The “gap period” is a none-transmission period in which a signal is not transmitted. The “gap period” is also referred to as a “guard period”, a “guard interval”, or a “transmitter transient period”. According to the 3rd Generation Partnership Project-Long Term Evolution (3GPP-LTE) communication standard, a time length of the “transmitter transient period” is defined to be a time length shorter than 17 microseconds.

The DAC 13 executes digital-to-analog conversion on the transmission signal output from the communication controlling section 12 so as to convert the transmission signal to an analog transmission signal and outputs the analog transmission signal to the mixer 15.

The oscillator 14 causes a signal with a predetermined frequency to oscillate and outputs the oscillating signal to the mixer 15.

The mixer 15 uses the signal output from the oscillator 14 to up-convert the analog transmission signal output from the DAC 13 so as to convert the analog transmission signal to a radio transmission signal and outputs the radio transmission signal to the amplifier 16.

The amplifier 16 amplifies the radio transmission signal output from the mixer 15 and outputs the amplified radio transmission signal to the Doherty amplifying circuit 17.

The Doherty amplifying circuit 17 includes a divider 31, a carrier amplifier (CA) 32, a λ/4 line 33, a λ/4 line 34, and a peak amplifier (PA) 35.

The divider 31 divides the radio transmission signal output from the amplifier 16 into two transmission signals, outputs one of the two transmission signals to the CA 32, and outputs the other of the two transmission signals to the PA 35 through the λ/4 line 34.

The CA 32 is, for example, a field-effect transistor (FET). The CA 32 is connected to the voltage switch 28, and a bias voltage is applied to the CA 32 from the voltage switch 28. Since the CA 32 is the FET or the like, the bias voltage is applied to a gate terminal of the CA 32 from the voltage switch 28. The CA 32 uses the applied bias voltage to amplify the transmission signal output from the divider 31 and outputs the amplified transmission signal to the λ/4 line 33. The CA 32 corresponds to an example of an “amplifier”.

The λ/4 line 33 is connected to an output terminal of the CA 32 and executes predetermined impedance conversion. The λ/4 line 34 is connected to an input terminal of the PA 35 and executes predetermined impedance conversion.

The PA 35 receives the transmission signal output from the divider 31 through the λ/4 line 34. If the level of the transmission signal upon the input of the transmission signal to the PA 35 is lower than a predetermined value, the PA 35 is in an OFF state. When the CA 32 reaches its saturated power level, the PA 35 becomes an ON state and operates together with the CA 32. Specifically, the PA 35 uses the bias voltage applied to a gate terminal of the PA 35 from the bias voltage generating section 24 to amplify the transmission signal output from the divider 31 and outputs the amplified transmission signal to a joint point at which an output of the λ/4 line 33 and an output of the PA 35 are connected to each other.

The coupler 18 divides, into transmission signals, the transmission signal received from the joint point at which the output of the λ/4 line 33 and the output of the PA 35 are connected to each other. Then, the coupler 18 outputs one of the transmission signals to the BPF 20 through the isolator 19 and outputs the other of the transmission signals to the mixer 22.

The isolator 19 removes a wave included in the received transmission signal and reflected by an antenna.

The BPF 20 removes, from the transmission signal received from the coupler 18 through the isolator 19, a component other than a predefined frequency band so as to obtain a transmission signal and transmits the obtained transmission signal to an external device through the antenna.

The oscillator 21 causes a signal with a predetermined frequency to oscillate and outputs the oscillating signal to the mixer 22.

The mixer 22 uses the signal output from the oscillator 21 to down-convert the signal output from the coupler 18 and outputs the down-converted signal to the ADC 23.

The ADC 23 executes analog-to-digital conversion on the signal output from the mixer 22 so as to convert the signal to a digital signal and outputs the digital signal as a feedback signal to the communication controlling section 12.

The bias voltage generating section 24 generates a bias voltage in accordance with control by the operating point voltage controlling section 29 and applies the generated bias voltage to the gate terminal of the PA 35. Specifically, the bias voltage generating section 24 includes a DAC 41 and an operational amplifier 42. The DAC 41 executes digital-to-analog conversion on a control signal received from the operating point voltage controlling section 29 so as to convert the control signal to an analog control signal and outputs the analog control signal to the operational amplifier 42. The operational amplifier 42 generates a fixed bias voltage based on the level of the analog control signal output from the DAC 41 and applies the generated bias voltage to the gate terminal of the PA 35.

The pinch-off voltage generating section 25 generates a pinch-off voltage and outputs the generated pinch-off voltage to the voltage switch 28. The pinch-off voltage is a voltage to be used to stop an amplification operation of the CA 32. For example, if the CA 32 is the FET, the pinch-off voltage is a control voltage to be applied to the gate terminal of the CA 32 and used to set a drain current within the CA 32 to 0.

The bias voltage generating section 26 generates a bias voltage in accordance with control by the operating point voltage controlling section 29 and outputs the generated bias voltage to the voltage switch 28. Specifically, the bias voltage generating section 26 includes a DAC 51 and an operational amplifier 52. The DAC 51 executes digital-to-analog conversion on a control signal output from the operating point voltage controlling section 29 so as to convert the control signal to an analog control signal and outputs the analog control signal to the operational amplifier 52. The operational amplifier 52 generates a fixed bias voltage based on the level of the analog control signal output from the DAC 51 and outputs the generated bias voltage to the voltage switch 28. The bias voltage output from the bias voltage generating section 26 is lower than a “temperature increase voltage” described later and higher than the pinch-off voltage. The bias voltage output from the bias voltage generating section 26 is an example of a “second voltage”. In order to simplify the following description, the bias voltage output from the bias voltage generating section 26 is merely referred to as a “bias voltage” in some cases.

The temperature increase voltage generating section 27 generates the temperature increase voltage and outputs the temperature increase voltage to the voltage switch 28. The temperature increase voltage is a voltage to be used to increase the temperature of the CA 32. For example, the temperature increase voltage generating section 27 generates a fixed temperature increase voltage by increasing a voltage obtained by dividing the bias voltage output from the bias voltage generating section 26. The temperature increase voltage output from the temperature increase voltage generating section 27 is an example of a “first voltage for increasing a temperature”. Relationships between the temperature increase voltage output from the temperature increase voltage generating section 27, the bias voltage output from the bias voltage generating section 26, and the pinch-off voltage output from the pinch-off voltage generating section 25 are described later.

The voltage switch 28 is connected to the pinch-off voltage generating section 25, the bias voltage generating section 26, and the temperature increase voltage generating section 27. The voltage switch 28 switches the operating point voltage (to be applied to the gate terminal of the CA 32) of the CA 32 between the pinch-off voltage output from the pinch-off voltage generating section 25, the bias voltage output from the bias voltage generating section 26, and the temperature increase voltage output from the temperature increase voltage generating section 27 in accordance with control by the operating point voltage controlling section 29.

For example, in the reception period, when receiving a “first switch control signal” from the operating point voltage controlling section 29, the voltage switch 28 selects the pinch-off voltage output from the pinch-off voltage generating section 25 and applies the selected pinch-off voltage to the gate terminal of the CA 32.

Thus, in the reception period, the amplification operation of the CA 32 is stopped. In the gap period after the reception period and before the transmission period, when receiving a “second switch control signal” from the operating point voltage controlling section 29, the voltage switch 28 selects the temperature increase voltage output from the temperature increase voltage generating section 27 and applies the selected temperature increase voltage to the gate terminal of the CA 32. Thus, in the gap period after the reception period and before the transmission period, the drain current flows in the CA 32 and thus the temperature of the CA 32 increases before the activation of the CA 32. In the transmission period, when receiving a “third switch control signal” from the operating point voltage controlling section 29, the voltage switch 28 selects the bias voltage output from the bias voltage generating section 26 and applies to the selected bias voltage to the gate terminal of the CA 32. Thus, in the transmission period, the CA 32 is activated and the amplification operation is executed by the CA 32.

The operating point voltage controlling section 29 sets the operating point voltage of the CA 32 to the temperature increase voltage in the gap period after the reception period and before the transmission period and sets the operating point voltage of the CA 32 to the bias voltage that is lower than the temperature increase voltage and higher than the pinch-off voltage in the transmission period.

For example, in the reception period, the operating point voltage controlling section 29 uses the aforementioned “first switch control signal” to set the operating point voltage of the CA 32 to the pinch-off voltage. In addition, for example, in the gap period after the reception period and before the transmission period, the operating point voltage controlling section 29 uses the aforementioned “second switch control signal” to set the operating point voltage of the CA 32 to the temperature increase voltage. In addition, for example, in the transmission period, the operating point voltage controlling section 29 uses the aforementioned “third switch control signal” to set the operating point voltage of the CA 32 to the bias voltage that is lower than the temperature increase voltage and higher than the pinch-off voltage.

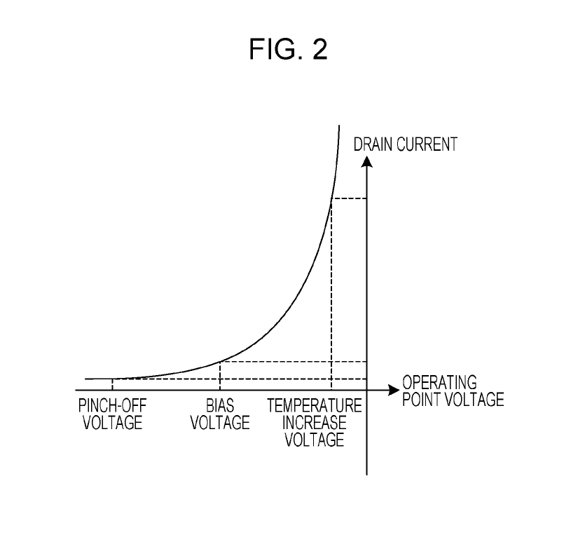

An example of the relationships between the temperature increase voltage output from the temperature increase voltage generating section 27, the bias voltage output from the bias voltage generating section 26, and the pinch-off voltage output from the pinch-off voltage generating section 25 is described below. FIG. 2 is a diagram describing the example of the relationships between the temperature increase voltage, the bias voltage, and the pinch-off voltage. In FIG. 2, an abscissa indicates the voltage applied to the gate terminal of the CA 32 or the operating point voltage, and an ordinate indicates the drain current corresponding to the operating point voltage.

As illustrated in FIG. 2, the pinch-off voltage is the lowest voltage, since the pinch-off voltage is used to set the drain current to 0. The bias voltage is lower than the temperature increase voltage and higher than the pinch-off voltage. The temperature increase voltage is higher than the pinch-off voltage and the bias voltage.

If the operating point voltage of the CA 32 is set to the temperature increase voltage, the drain current flowing in the CA 32 is larger than that in a case where the operating point voltage of the CA 32 is set to the bias voltage. This means that if the operating point voltage of the CA 32 is set to the temperature increase voltage, the temperature of the CA 32 rapidly increases.

The temperature increase voltage is determined in advance so as to ensure that the amount of heat generated from the CA 32 in response to the temperature increase voltage in the gap period is equal to the amount of heat generated from the CA 32 in response to the bias voltage in the transmission period.

This feature is described below using specific numeral values. It is assumed that the ambient temperature of the radio communication device 10 is 25° C., the amount of an increase in the temperature of the inside of the radio communication device 10 due to heat generated from a part that is included in the radio communication device 10 and is not the CA 32 is 30° C., a power supply voltage (drain voltage) of the CA 32 is 50 V, and the amount of heat generated from the CA 32 in response to the bias voltage in the transmission period is 70 W. In addition, it is assumed that thermal resistance of the CA 32 is 1.4° C./W. In this case, the temperature of the inside of the radio communication device 10 in the transmission period is 153° C. (=70×1.4+25+30).

It is assumed that the drain current in the case where the operating point voltage of the CA 32 is set to the temperature increase voltage is Id. In this case, the temperature of the inside of the radio communication device 10 in the gap period is 1.4×(50×Id)+25+30. If the amount of heat generated from the CA 32 in response to the temperature increase voltage in the gap period is equal to the amount of heat generated from the CA 32 in response to the bias voltage in the transmission period, the following equation is established: 1.4×(50×Id)+25+30=153. Specifically, if the amount of heat generated from the CA 32 in response to the temperature increase voltage in the gap period is equal to the amount of heat generated from the CA 32 in response to the bias voltage in the transmission period, the drain current Id flowing in the CA 32 is 1.4 A. Thus, the temperature increase voltage is determined to be a voltage that causes the drain current Id flowing in the CA 32 to be equal to 1.4 A. Thus, the difference between the temperature of the inside of the radio communication device 10 in the transmission period and the temperature of the inside of the radio communication device 10 in the gap period may be suppressed and a change in the temperature of the CA 32 upon the start of the transmission period (or upon the activation of the CA 32) may be suppressed.

Example of Process Operations of Radio Communication Device

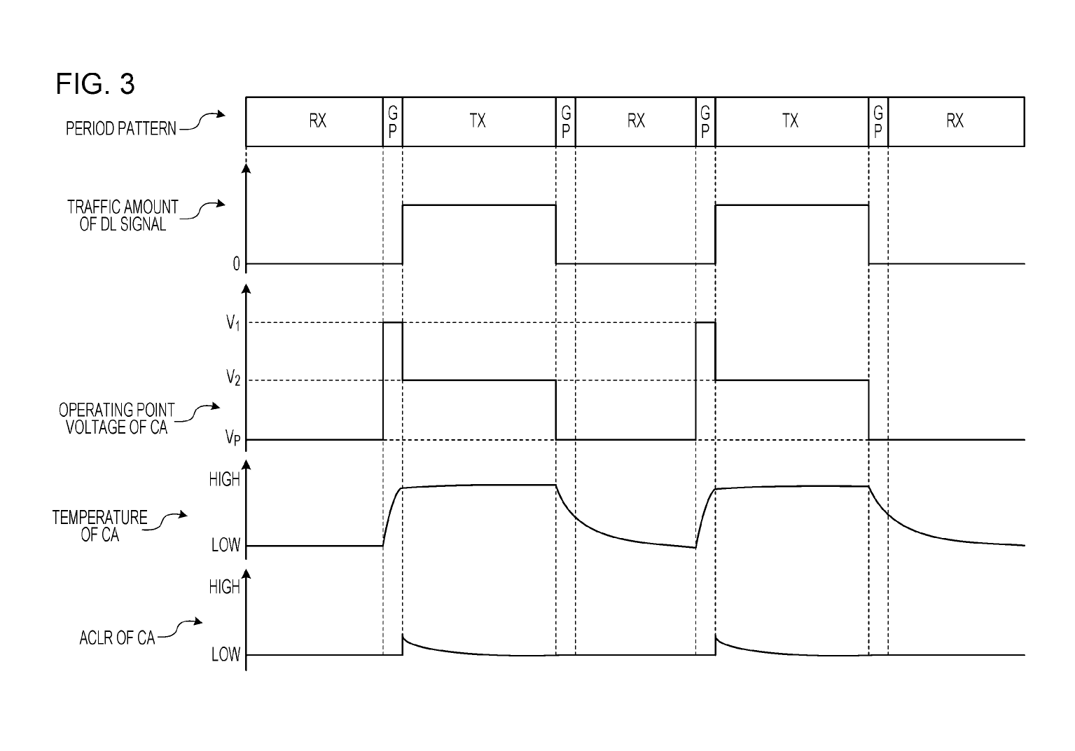

Next, an example of process operations of the radio communication device 10 according to the first embodiment is described. FIG. 3 is a diagram describing the process operations of the radio communication device according to the first embodiment.

As indicated in the top row of FIG. 3, it is assumed that periods change in order of a reception period (indicated by “RX” in FIG. 3), a gap period (indicated by “GP” in FIG. 3), a transmission period (indicated by “TX” in FIG. 3), a gap period, and a reception period in accordance with the time division duplex scheme.

As indicated in the third row from the top of FIG. 3, in reception periods, the operating point voltage controlling section 29 sets the operating point voltage of the CA 32 to the pinch-off voltage. Thus, in the reception periods, the drain current of the CA 32 is 0 and the amplification operation of the CA 32 is stopped.

In addition, as indicated in the third row from the top of FIG. 3, in gap periods after the reception periods and before transmission periods, the operating point voltage controlling section 29 changes the operating point voltage of the CA 32 from the pinch-off voltage Vp to the temperature increase voltage V1. Thus, in the gap periods after the reception periods and before the transmission periods, the drain current flows in the CA 32 and, as a result, the temperature of the CA 32 increases before the activation of the CA 32 (refer to the fourth row from the top of FIG. 3).

In addition, as indicated in the third row from the top of FIG. 3, in the transmission periods, the operating point voltage controlling section 29 changes the operating point voltage of the CA 32 from the temperature increase voltage V1 to the bias voltage V2. Thus, in the transmission periods, the CA 32 is activated and the amplification operation is executed by the CA 32.

As indicated in the second row from the top of FIG. 3, in the transmission periods, a traffic amount of the transmission signal transmitted from the transmission signal generating section 11 increases from 0. Thus, the transmission signal is input to the activated CA 32 and amplified by the CA 32.

The temperature of the CA 32 in the gap periods after the reception periods and before the transmission periods affects a change in the temperature of the CA 32 upon the start of the transmission period (or upon the activation of the CA 32). Specifically, in the gap periods after the reception periods and before the transmission periods, if the temperature of the CA 32 increases in advance, the change in the temperature of the CA 32 upon the start of the transmission period is relatively gradual, as indicated in the fourth row from the top of FIG. 3. As described above, in the first embodiment, the operating point voltage of the CA 32 is set to the temperature increase voltage in the gap periods after the reception periods and before the transmission periods and is set to the bias voltage in the transmission periods. Thus, the change in the temperature of the CA 32 upon the start of the transmission period (or upon the activation of the CA 32) mainly contributing to an increase in an ACLR may be gradual and thus the increase in the ACLR may be suppressed. The ACLR of the CA 32 is schematically illustrated in the bottom row of FIG. 3.

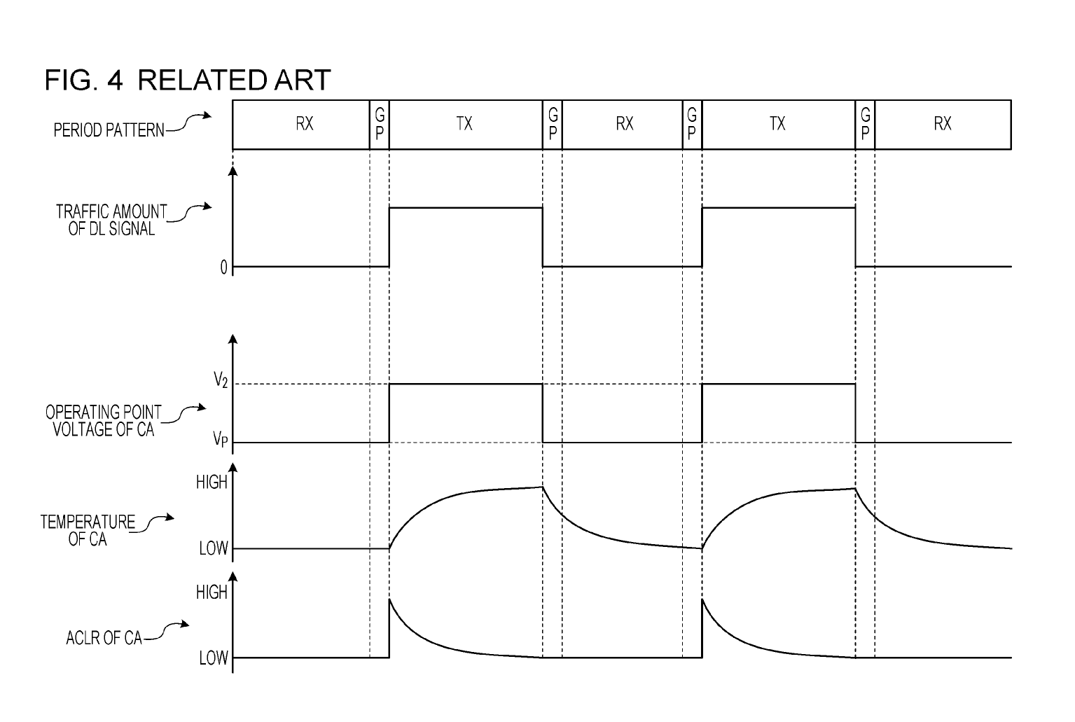

Process operations of a radio communication device according to a comparative example in which the temperature of the CA 32 does not increase in the gap periods after the reception periods and before the transmission periods are described below. FIG. 4 is a diagram describing the process operations of the radio communication device according to the comparative example. The radio communication device according to the comparative example does not include the temperature increase voltage generating section 27, differently from the radio communication device 10 according to the first embodiment. In addition, the radio communication device according to the comparative example includes a voltage switch for switching the operating point voltage of the CA 32 between the pinch-off voltage output from the pinch-off voltage generating section 25 and the bias voltage output from the bias voltage generating section 26, instead of the voltage switch 28.

In an example illustrated in FIG. 4, it is assumed that the periods change in order of the reception period (indicated by “RX” in FIG. 4), the gap period (indicated by “GP” in FIG. 4), the transmission period (indicated by “TX” in FIG. 4), the gap period, and the reception period in accordance with the time division duplex scheme in the same manner as FIG. 3.

In the comparative example, the operating point voltage of the CA 32 is set to the pinch-off voltage Vp in the periods other than the transmission periods and is set to the bias voltage V2 in the transmission periods, as indicated in the third row from the top of FIG. 4. In the comparative example, in the gap periods after the reception periods and before the transmission periods, the operating point voltage of the CA 32 is not set to the temperature increase voltage V1. Thus, in the gap periods after the reception periods and before the transmission periods, the drain current does not flow in the CA 32 and, as a result, the temperature of the CA 32 does not increase before the activation of the CA 32 (refer to the fourth row from the top of FIG. 4). Then, the temperature of the CA 32 becomes relatively low and rapidly increases upon the start of the transmission period (or upon the activation of the CA 32), as indicated in the fourth row from the top of FIG. 4. The rapid increases in the temperature of the CA 32 may deteriorate AM/AM and AM/PM characteristics of the CA 32 and, as a result, the ACLR may easily increase. The ACLR of the CA 32 according to the CA 32 is schematically illustrated in the bottom row of FIG. 4.

Flow of Process Operations of Radio Communication Device

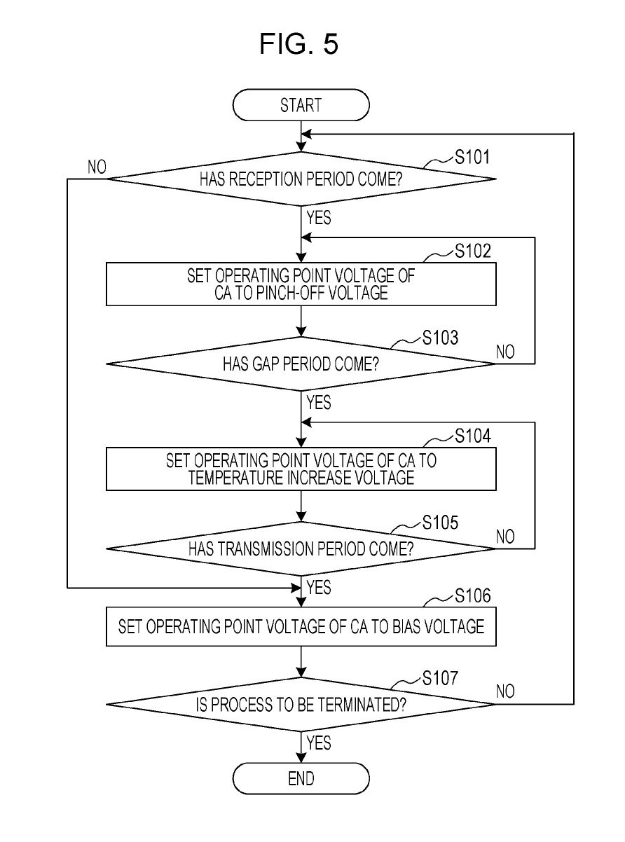

Next, the flow of the process operations of the radio communication device according to the first embodiment is described. Especially, a method of setting the operating point voltage of the CA 32 by the operating point voltage controlling section 29 of the radio communication device 10 is described below. FIG. 5 is a flowchart indicating an example of the flow of the process operations of the radio communication device according to the first embodiment.

As illustrated in FIG. 5, when a reception period has come (Yes in S101), the operating point voltage controlling section 29 sets the operating point voltage of the CA 32 to the pinch-off voltage (in S102). If the reception period has not yet come (No in S101), a transmission period has come and the operating point voltage controlling section 29 causes a process to proceed to S106.

If a gap period has not yet come after the reception period and before a transmission period (No in S103), the operating point voltage controlling section 29 causes the process to return to S102. If the gap period has come after the reception period and before the transmission period (Yes in S103), the operating point voltage controlling section 29 sets the operating point voltage of the CA 32 to the temperature increase voltage (in S104).

If the transmission period has not yet come (No in S105), the operating point voltage controlling section 29 causes the process to return to S104. If the transmission period has come (Yes in S105), the operating point voltage controlling section 29 sets the operating point voltage of the CA 32 to the bias voltage (in S106). After that, if a gap period has come after the transmission period and before a reception period, the operating point voltage controlling section 29 sets the operating point voltage of the CA 32 to the pinch-off voltage.

If the process is not to be terminated (No in S107), the operating point voltage controlling section 29 causes the process to return to S101 and repeatedly executes S101 to S107. If the process is to be terminated (Yes in S107), the operating point voltage controlling section 29 terminates the process illustrated in FIG. 5.

According to the first embodiment, the CA 32 amplifies the transmission signal in the radio communication device 10 to which the time division duplex scheme is applied. Then, the operating point voltage controlling section 29 sets the operating point voltage of the CA 32 to the temperature increase voltage in a gap period after a reception period and before a transmission period. Then, in the transmission period, the operating point voltage controlling section 29 sets the operating point voltage of the CA 32 to the bias voltage that is lower than the temperature increase voltage and higher than the pinch-off voltage.

In the configuration of the radio communication device 10, the change in the temperature of the CA 32 upon the start of the transmission period (or upon the activation of the CA 32) may be gradual, and an increase in the ACLR that is caused by the change in the temperature of the CA 32 upon the activation of the CA 32 may be suppressed.

### Second Embodiment

In the case where the temperature increase voltage to be set as the operating point voltage of the CA 32 is a fixed value, an increase in the temperature of the CA 32 in a gap period after a reception period and before a transmission period may be excessive. To avoid this, the temperature increase voltage is changed based on the traffic amount of the transmission signal in the second embodiment.

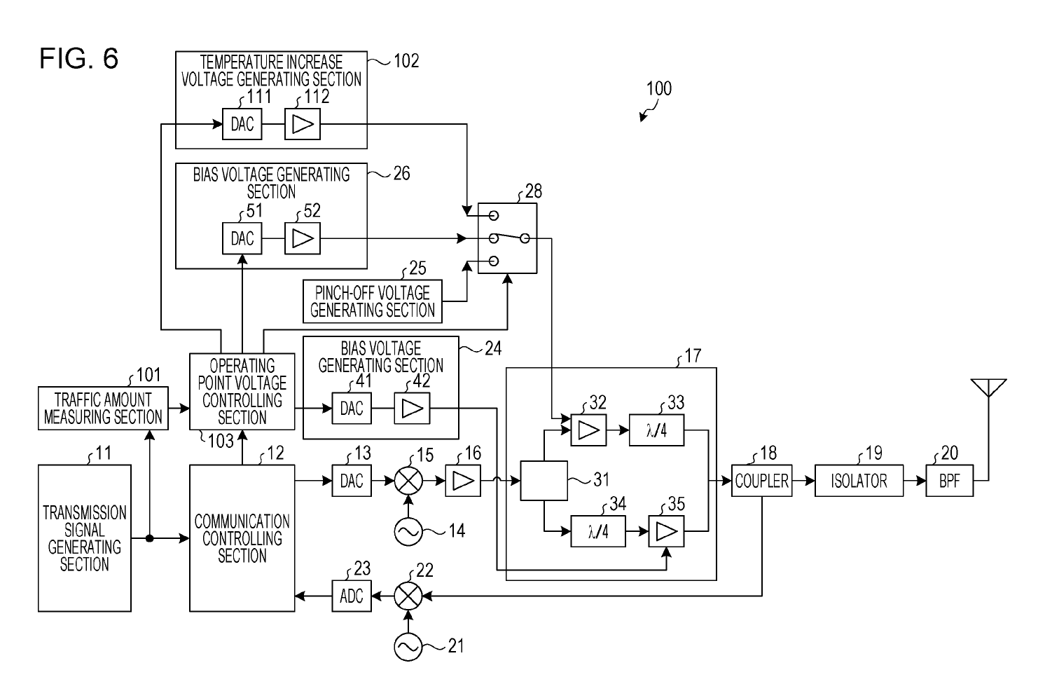

FIG. 6 is a block diagram illustrating an example of a configuration of a radio communication device according to the second embodiment. Referring to FIG. 6, a radio communication device 100 includes a traffic amount measuring section 101. In addition, the radio communication device 100 includes a temperature increase voltage generating section 102, instead of the temperature increase voltage generating section 27 described in the first embodiment. In addition, the radio communication device 100 includes an operating point voltage controlling section 103, instead of the operating point voltage controlling section 29 described in the first embodiment.

The traffic amount measuring section 101 measures the traffic amount of the transmission signal output from the transmission signal generating section 11.

The temperature increase voltage generating section 102 generates a variable temperature increase voltage in accordance with control by the operating point voltage controlling section 103 and outputs the generated temperature increase voltage to the voltage switch 28. Specifically, the temperature increase voltage generating section 102 includes a DAC 111 and an operational amplifier 112. The DAC 111 executes digital-to-analog conversion on a “temperature increase voltage change signal” output from the operating point voltage controlling section 103 so as to convert the “temperature increase voltage change signal” to an analog control signal and outputs the analog control signal to the operational amplifier 112. The operational amplifier 112 generates a temperature increase voltage indicating the analog control signal output from the DAC 111 or the “temperature increase voltage change signal” and outputs the generated temperature increase voltage to the voltage switch 28.

The operating point voltage controlling section 103 sets the operating point voltage of the CA 32 to the temperature increase voltage in the gap period after the reception period and before the transmission period in the same manner as the operating point voltage controlling section 29 described in the first embodiment. In addition, the operating point voltage controlling section 103 sets the operating point voltage of the CA 32 to the bias voltage that is lower than the temperature increase voltage and higher than the pinch-off voltage in the transmission period in the same manner as the operating point voltage controlling section 29 described in the first embodiment.

Furthermore, the operating point voltage controlling section 103 changes the aforementioned “temperature increase voltage” based on the traffic amount measured by the traffic amount measuring section 101. For example, the operating point voltage controlling section 103 holds association data in which the traffic amount and the temperature increase voltage are associated with each other. The operating point voltage controlling section 103 acquires, from the association data, the temperature increase voltage associated with the traffic amount measured by the traffic amount measuring section 101. Then, the operating point voltage controlling section 103 uses the aforementioned “temperature increase voltage change signal” indicating the temperature increase voltage acquired from the association data to change the temperature increase voltage to be generated by the temperature increase voltage generating section 102.

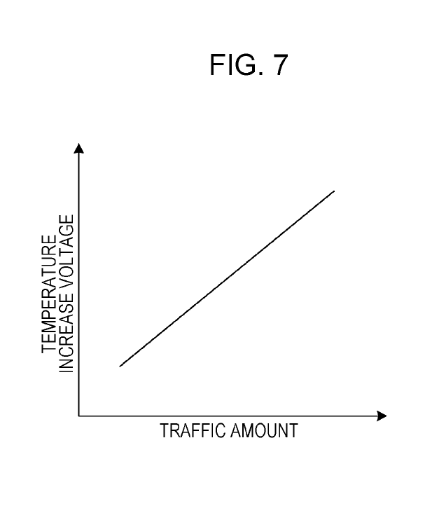

FIG. 7 is a diagram illustrating an example of the association data in which the traffic amount and the temperature increase voltage are associated with each other. In the association data illustrated in FIG. 7, as the traffic amount is reduced, the temperature increase voltage is reduced. If the traffic amount measured by the traffic amount measuring section 101 is T1, the operating point voltage controlling section 103 uses the association data illustrated in FIG. 7 to change the temperature increase voltage to a voltage V1. If the traffic amount measured by the traffic amount measuring section 101 is T2 that is smaller than T1, the operating point voltage controlling section 103 uses the association data illustrated in FIG. 7 to change the temperature increase voltage to a voltage V1′ that is lower than V1.

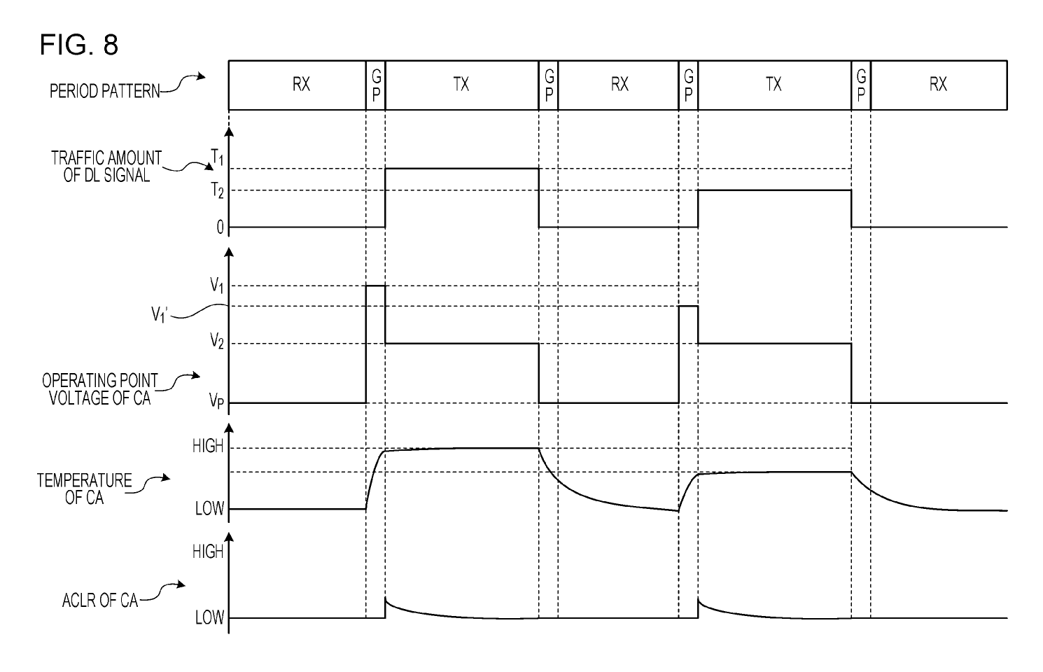

Next, an example of process operations of the radio communication device 100 according to the second embodiment is described. FIG. 8 is a diagram describing the process operations of the radio communication device according to the second embodiment.

As indicated in the top row of FIG. 8, it is assumed that the periods change in order of the reception period (indicated by “RX” in FIG. 8), the gap period (indicated by “GP” in FIG. 8), the transmission period (indicated by “TX” in FIG. 8), the gap period, and the reception period in accordance with the time division duplex scheme.

As indicated in the third row from the top of FIG. 8, the operating point voltage controlling section 103 sets the operating point voltage of the CA 32 to the pinch-off voltage in the reception periods. Thus, in the reception periods, the drain current of the CA 32 is 0 and the amplification operation of the CA 32 is stopped.

In addition, as indicated in the third row from the top of FIG. 8, in the gap period after the first reception period and before the first transmission period, the operating point voltage controlling section 103 changes the operating point voltage of the CA 32 from the pinch-off voltage Vp to the temperature increase voltage V1. Thus, in the gap period after the first reception period and before the first transmission period, the drain current flows in the CA 32 and, as a result, the temperature of the CA 32 increases before the activation of the CA 32 (refer to the fourth row from the top of the FIG. 8).

In addition, as indicated in the third row from the top of FIG. 8, in the first transmission period, the operating point voltage controlling section 103 changes the operating point voltage of the CA 32 from the temperature increase voltage V1 to the bias voltage V2. Thus, in the first transmission period, the CA 32 is activated and the amplification operation is executed by the CA 32.

Then, as indicated in the second row from the top of FIG. 8, in the first transmission period, the traffic amount of the transmission signal to be transmitted by the transmission signal generating section 11 increases from 0 to T1. Thus, the transmission signal is input to the activated CA 32 and amplified by the CA 32.

The temperature of the CA 32 in the gap period after the first reception period and before the first transmission period affects a change in the temperature of the CA 32 upon the start of the first transmission period (or upon the activation of the CA 32). Specifically, in the gap period after the first reception period and before the first transmission period, if the temperature of the CA 32 increases in advance, the change in the temperature of the CA 32 upon the start of the transmission period is relatively gradual, as indicated in the fourth row from the top of FIG. 8. As described above, in the second embodiment, the operating point voltage of the CA 32 is set to the temperature increase voltage V1 in the gap period after the first reception period and before the first transmission period and is set to the bias voltage V2 in the first transmission period. Thus, the change in the temperature of the change 32 upon the start of the transmission period (or upon the activation of the CA 32) mainly contributing to an increase in the ACLR may be gradual, and the increase in the ACLR may be suppressed. The ACLR of the CA 32 is schematically illustrated in the bottom row of FIG. 8.

In addition, as indicated in the third row from the top of FIG. 8, in the gap period after the second reception period and before the second transmission period, the operating point voltage controlling section 103 changes the operating point voltage of the CA 32 from the pinch-off voltage Vp to the temperature increase voltage V1′. Specifically, since the traffic amount measured by the traffic amount measuring section 101 is reduced from T1 to T2, the operating point voltage controlling section 103 changes the temperature increase voltage from V1 to V1′ that is lower than V1. Thus, in the gap period after the second reception period and before the second transmission period, the drain current flows in the CA 32 and, as a result, the temperature of the CA 32 increases before the activation of the CA 32 (refer to the fourth row from the top of FIG. 8). However, since the temperature increase voltage is changed from V1 to V1′, an increase in the temperature of the CA 32 is smaller than the increase in the temperature of the CA 32 in the gap period after the first reception period and before the first transmission period.

In addition, as indicated in the third row from the top of FIG. 8, in the second transmission period, the operating point voltage controlling section 103 changes the operating point voltage of the CA 32 from the temperature increase voltage V1′ to the bias voltage V2. Thus, in the second transmission period, the CA 32 is activated and the amplification operation is executed by the CA 32.

The temperature of the CA 32 in the gap period after the second reception period and before the second transmission period affects a change in the temperature of the CA 32 upon the start of the second transmission period (or upon the activation of the CA 32). Specifically, in the gap period after the second reception period and before the second transmission period, if the temperature of the CA 32 increases in advance, the change in the temperature of the CA 32 upon the start of the second transmission period is relatively gradual, as indicated in the fourth row from the top of FIG. 8.

As described above, in the second embodiment, the operating point voltage of the CA 32 is set to the temperature increase voltage V1′ in the gap period after the second reception period and before the second transmission period and is set to the bias voltage V2 in the second transmission period. Thus, the change in the temperature of the CA 32 upon the start of the transmission period (or upon the activation of the CA 32) mainly contributing to an increase in the ACLR may be gradual and the increase in the ACLR may be suppressed. The ACLR of the CA 32 is schematically illustrated in the bottom row of FIG. 8. As described above, in the second embodiment, since the temperature increase voltage is changed based on the traffic amount of the transmission signal, an excessive increase in the temperature of the CA 32 is avoided.

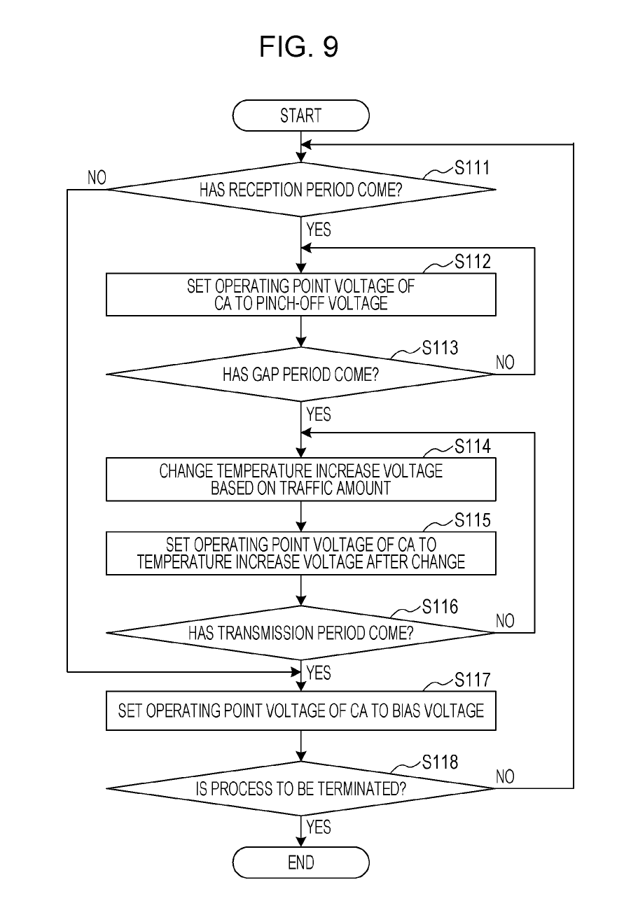

Next, the flow of the process operations of the radio communication device according to the second embodiment is described. Especially, a method of setting the operating point voltage of the CA 32 by the operating point voltage controlling section 103 of the radio communication device 100 is described below. FIG. 9 is a flowchart indicating an example of the flow of the process operations of the radio communication device according to the second embodiment.

As illustrated in FIG. 9, if a reception period has come (Yes in S111), the operating point voltage controlling section 103 sets the operating point voltage to the pinch-off voltage (in S112). If the reception period has not yet come (No in S111), a transmission period has come and the operating point voltage controlling section 103 causes a process to proceed to S117.

If a gap period has not yet come after the reception period and before a transmission period (No in S113), the operating point voltage controlling section 103 causes the process to proceed to S112. If the gap period has come after the reception period and before the transmission period (Yes in S113), the operating point voltage controlling section 103 changes, based on the traffic amount measured by the traffic amount measuring section 101, the temperature increase voltage to be generated by the temperature increase voltage generating section 102 (in S114). Then, the operating point voltage controlling section 103 sets the operating point voltage of the CA 32 to the temperature increase voltage after the change (in S115).

If the transmission period has not yet come (No in S116), the operating point voltage controlling section 103 causes the process to return to S114. If the transmission period has come (Yes in S116), the operating point voltage controlling section 103 sets the operating point voltage of the CA 32 to the bias voltage (in S117). After that, if a gap period has come after the transmission period and before a reception period, the operating point voltage controlling section 103 sets the operating point voltage of the CA 32 to the pinch-off voltage.

If the process is not to be terminated (No in S118), the operating point voltage controlling section 103 causes the process to return to S111 and repeatedly executes S111 to S118. If the process is to be terminated (Yes in S118), the operating point voltage controlling section 103 terminates the process illustrated in FIG. 9.

According to the second embodiment, in the radio communication device 100, the operating point voltage controlling section 103 changes the aforementioned “temperature increase voltage” based on the traffic amount measured by the traffic amount measuring section 101.

In the configuration of the radio communication device 100, the temperature increase voltage is changed to a value based on the traffic amount, and thus an excessive increase in the temperature of the CA 32 may be avoided and an increase in the ACLR may be suppressed.

### Another Embodiment

The constituent elements of the sections illustrated in the first and second embodiments may not be physically configured as illustrated in the drawings. Specifically, the specific forms of the division and integration of the sections are not limited to those illustrated in the drawings, and all or a part of the sections may be functionally or physically divided or integrated on an arbitrary unit based on loads and usage statuses of the sections.

All or a part of the various process functions to be executed by the devices may be executed on a central processing unit (CPU) (or a microcomputer such as a microprocessing unit (MPU) or a microcontroller unit (MCU)). All or a part of the various process functions may be executed on a program to be analyzed and executed by the CPU (or the microcomputer such as the MPU or the MCU) or may be executed on hardware based on wired logic.

The radio communication devices according to the first and second embodiments may be achieved by the following hardware configuration.

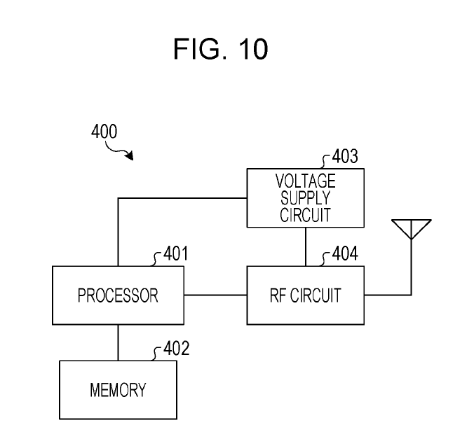

FIG. 10 is a diagram illustrating an example of the hardware configuration of each of the radio communication devices. As illustrated in FIG. 10, a radio communication device 400 includes a processor 401, a memory 402, a voltage supply circuit 403, and an RF circuit 404. Examples of the processor 401 are a CPU, a digital signal processor (DSP), and a field programmable gate array (FPGA). Examples of the memory 402 are a random access memory (RAM) such as a synchronous dynamic random access memory (SDRAM), a read only memory (ROM), and a flash memory.

The various process functions to be executed in the radio communication devices according to the first and second embodiments may be achieved by causing the processor to execute programs stored in a memory such as a nonvolatile storage medium. Specifically, the programs that correspond to the processes to be executed by the transmission signal generating section 11, the communication controlling section 12, the operating point voltage controlling sections 29 and 103, and the traffic amount measuring section 101 are stored in the memory 402 and executed by the processor 401. The DAC 13, the oscillator 14, the mixer 15, the amplifier 16, the Doherty amplifying circuit 17, the coupler 18, the isolator 19, the BPF 20, the oscillator 21, the mixer 22, and the ADC 23 are achieved by the RF circuit 404. The bias voltage generating section 24, the pinch-off voltage generating section 25, the bias voltage generating section 26, the temperature increase voltage generating sections 27 and 102, the voltage switch 28, and the operating point voltage controlling sections 29 and 103 are achieved by the voltage supply circuit 403.

The various process functions to be executed in the radio communication devices according to the first and second embodiments are executed by the single processor 401, but are not limited to this. The various process functions to be executed in the radio communication devices according to the first and second embodiments may be executed by multiple processors.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A radio communication device, comprising:
an amplifier configured to amplify an electric signal to be transmitted; and
a controlling section configured to set an operating point voltage of the amplifier to a first voltage for increasing a temperature of the amplifier in a non-transmission period after a reception period and before a transmission period and set the operating point voltage of the amplifier to a second voltage that is lower than the first voltage and higher than a pinch-off voltage in the transmission period.

2. The radio communication device according to claim 1,
wherein the first voltage is determined so as to ensure that an amount of heat generated from the amplifier in response to the first voltage in the non-transmission period is equal to the amount of heat generated from the amplifier in response to the second voltage in the transmission period.

3. The radio communication device according to claim 1, further comprising:
a measuring section configured to measure a traffic amount of the electric signal to be transmitted,
wherein the controlling section changes the first voltage based on the measured traffic amount.

4. The radio communication device according to claim 1,
wherein the amplifier is a Field-Effect Transistor.
